(19) United States
(12) Patent Application Publication
(10) Pub. No.: US 2017/0338191 A1
(43) Pub. Date: Nov. 23, 2017

(54) THROUGH SILICON VIA CHIP AND MANUFACTURING METHOD THEREOF, FINGERPRINT IDENTIFICATION SENSOR AND TERMINAL DEVICE

(71) Applicant: SHENZHEN GOODIX TECHNOLOGY CO., LTD., Shenzhen (CN)

(72) Inventor: Baoquan WU, Shenzhen (CN)

(21) Appl. No.: 15/656,546

(22) Filed: Jul. 21, 2017

Related U.S. Application Data
(63) Continuation of application No. PCT/CN2016/103055, filed on Oct. 24, 2016.

(30) Foreign Application Priority Data
May 19, 2016 (CN) 201620460572.2

(51) Int. Cl. H01L 23/00; H01L 23/48; H01L 23/31; H01L 21/78; G06K 9/00; H01L 21/768; H01L 21/56; H01L 23/528; H01L 23/29

(52) U.S. Cl. CPC H01L 23/562; H01L 23/528; H01L 23/481; H01L 23/3178; H01L 23/293; G06K 9/00087; H01L 21/76898; H01L 21/565; H01L 21/561; H01L 21/78

(57) ABSTRACT

A through silicon via chip and manufacturing method thereof are provided, where the through silicon via chip includes a silicon substrate, the silicon substrate is provided with a via, the via is an oblique via, and a backfill structure layer is disposed in the via. According to the through silicon via chip and manufacturing method thereof, a fingerprint identification sensor and a terminal device, a backfill structure is added in an oblique via to play a supportive role when a force is exerted on a surface of the through silicon via chip, which avoids a fracture of the through silicon via chip, thereby enhancing structural strength of the through silicon via chip.

### CROSS-REFERENCE TO RELATED APPLICATIONS

This application is a continuation of International Application No. PCT/CN2016/103055, filed on Oct. 24, 2016, which claims priority to Chinese Patent Application No. 201620460572.2, filed on May 19 2016. The disclosures of the aforementioned applications are hereby incorporated by reference in their entireties.

### TECHNICAL FIELD

The present application relates to the field of packaging technologies, and in particular, to a through silicon via chip and manufacturing method thereof, a fingerprint identification sensor and a terminal device.

### BACKGROUND

A wafer level through silicon via packaging technology is widely used in consumer electronic chips. Currently, a large number of oblique through silicon vias are applied to consumer electronic products, such as an image identification sensor, and the oblique through silicon via has advantages of low manufacturing difficulty and low cost.

An oblique through silicon via chip has a step structure. In a case of a through silicon via chip die, a fracture occurs easily at the step when a test and a process such as surface bonding and welding are performed.

### SUMMARY

Embodiments of the present application provide a through silicon via chip and manufacturing method thereof, a fingerprint identification sensor and a terminal device, which can enhance structural strength of the through silicon via chip.

According to a first aspect, a through silicon via chip is provided, where the through silicon via chip comprises a silicon substrate, the silicon substrate is provided with a via, the via is an oblique via, and a backfill structure layer is disposed in the via.

A via is disposed on the substrate, and the via may be achieved by etching, so that electrical interconnection is performed between an element of an upper surface of the silicon substrate and another element at a lower surface of the though silicon via chip. The through silicon via chip fractures easily since a lower part of the via is hollow. Therefore, in an embodiment of the present application, the backfill structure layer is disposed at the lower part of the via for supporting the through silicon via chip, and a lower surface of the backfill structure layer is flush with the lower surface of the through silicon via chip. This can facilitate subsequent surface mounting and welding, and enhance structural strength of the through silicon via chip.

With reference to the first aspect, in a first possible implementation manner of the first aspect, the lower surface of the backfill structure layer 230 is flush with the lower surface of the through silicon via chip.

In this case, in the subsequent surface mounting and welding, a contact area of a bottom of the through silicon via chip is larger, which is beneficial to apportioning pressure, thereby enhancing the structural strength of the through silicon via chip.

With reference to the first aspect or the first possible implementation manner of the first aspect, in a second possible implementation manner of the first aspect, a first insulating layer, a rewiring metal layer and a second insulating layer are orderly disposed between the backfill structure layer and the silicon substrate.

The rewiring metal layer is disposed between the backfill structure layer and the silicon substrate, and the rewiring metal layer passes through the via to implement conduction between the rewiring metal layer and another element at the lower surface of the through silicon via chip. Since a material of the silicon substrate is silicon, an insulating layer should be disposed between the rewiring metal layer and the silicon substrate, an insulating layer should also be disposed between the rewiring metal layer and the backfill structure layer, and these insulating layers play a protective role. The first insulating layer and the second insulating layer may be the same or different, which is not limited in the present application.

With reference to the second possible implementation manner of the first aspect, in a third possible implementation manner of the first aspect, a surface pad is disposed at a top of the via, and a lower surface of the surface pad is connected with the rewiring metal layer.

The surface pad is connected with the rewiring metal layer, that is, no insulating layer is disposed between the surface pad and the rewiring metal layer. The via may be configured in a manner that the first insulating layer, the rewiring metal layer and the second insulating layer are orderly disposed outwardly from a center axis of the via, and only the rewiring metal layer is connected with the surface pad. In this case, the surface pad of the through silicon via chip is conductive with the rewiring metal layer to implement electrical interconnection between an electrical element at an upper surface of the through silicon via chip and an electrical element at the lower surface of the through silicon via chip.

With reference to the first aspect, in a fourth possible implementation manner of the first aspect, a wall of the via is at an angle of 60 degree with respect to an upper surface of the through silicon via chip.

The via may also be a connection of a plurality of via structures with different apertures and the like, which is not limited in the present application. The via, for example, may be configured in a manner that the wall is at an angle of 60 degree with respect to the upper surface of the through silicon via chip, thereby reducing manufacturing difficulty.

With reference to the first aspect, in a fifth possible implementation manner of the first aspect, the silicon substrate is provided with a plurality of the vias.

In the present application, the plurality of the vias may implement interconnection between different surface pads of an upper surface of the silicon substrate, or electrical interconnection between the upper surface of the silicon substrate and an electrical element at the lower surface of the through silicon via chip.

According to a second aspect, a fingerprint identification sensor is provided, where the fingerprint identification sensor includes the though silicon via chip according to the first aspect.

According to a third aspect, a terminal device is provided, where the terminal device includes the though silicon via chip according to the first aspect.

Based on the foregoing technical solutions, according to a though silicon via chip of the embodiments of the present application, a backfill structure layer is added in an oblique via to play a supportive role when a force is exerted on a surface of the through silicon via chip, which avoids a fracture of the through silicon via chip, thereby enhancing structural strength of the through silicon via chip.

### BRIEF DESCRIPTION OF DRAWINGS

To describe technical solutions in embodiments of the present application more clearly, the following briefly introduces accompanying drawings required for describing the embodiments of the present application. Apparently, the accompanying drawings in the following description show merely some embodiments of the present application, and a person of ordinary skill in the art may still derive other drawings from these accompanying drawings without creative efforts.

FIG. 1 is a sectional view of a general through silicon via chip;

FIG. 2 is a sectional view of a through silicon via chip according to an embodiment of the present application;

FIG. 3 is a schematic view of an inverted wafer level through silicon via chip according to an embodiment of the present application;

FIG. 4 is a schematic view of a wafer level through silicon via chip provided with a structure backfill layer according to an embodiment of the present application; and

FIG. 5 is a schematic view of a single through silicon via chip according to an embodiment of the present application.

### DESCRIPTION OF EMBODIMENTS

The following clearly and completely describes technical solutions in embodiments of the present application with reference to accompanying drawings in the embodiments of the present application. Apparently, the described embodiments are a part rather than all of the embodiments of the present application. All other embodiments obtained by a person of ordinary skill in the art based on the embodiments of the present application without creative efforts shall fall within the protection scope of the present application.

A through silicon via chip according to the embodiments of the present application may be applied to a terminal device, and the terminal device may include but is not limited to a cell phone, a tablet computer, an electronic book, a mobile station, or the like.

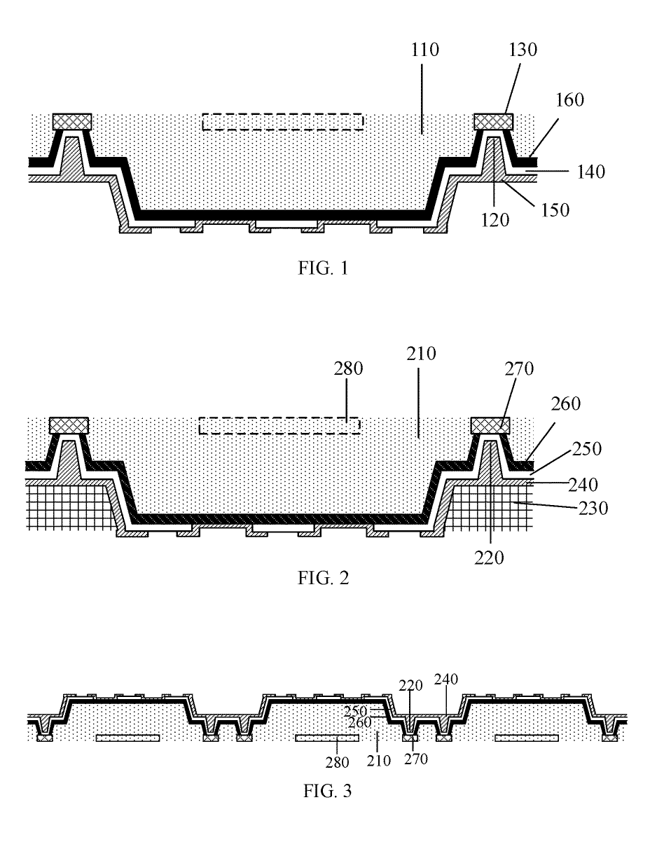

Referring to FIG. 1, a via is generally formed in a silicon substrate 110 by two-stage etching for an oblique through silicon via chip, and the via includes a small hole 120 at an upper part and a large hollow hole at a lower part, as shown in FIG. 1. A rewiring metal layer 140 in the via enables a surface pad 130 of an upper surface of the through silicon via chip to be electronically interconnected with another element at a lower surface of the though silicon via chip. A wall of the via and the rewiring metal layer 140 are isolated from each other through an insulating layer 160, and the rewiring metal layer 140 is provided with an insulating layer 150 for protection. For example, FIG. 1 shows a single through silicon via chip. In this case, the small hole 120 may be regarded as a protruding step, and the large hole is hollow. A fracture occurs easily at the step when a test and a process such as surface bonding and welding are performed.

FIG. 2 shows a partial sectional view of a through silicon via chip according to an embodiment of the present application. As shown in FIG. 2, the through silicon via chip includes a silicon substrate 210, the silicon substrate 210 is provided with a via 220, the via 220 is an oblique via, and a backfill structure layer 230 is disposed in the via 220.

Specifically, as shown in FIG. 2, the via 220 in the silicon substrate 210 is a step structure, including a small hole at an upper part and a large hole at a lower part, and the via 220 may be achieved by two-stage etching. The through silicon via chip is easily fractured at the protruding step structure of the through silicon via chip since the large hole at the lower part of the via 220 is hollow. Therefore, in the embodiment of the present application, the backfill structure layer 230 is disposed in the via 220 for supporting the protruding step structure of the through silicon via chip.

It should be understood that, the via is formed by enclosing of a wall, and the wall is the silicon substrate.

Therefore, according to the though silicon via chip of the embodiment of the present application, the backfill structure layer 230 is added in the oblique via to play a supportive role when a force is exerted on a surface of the through silicon via chip, which avoids a fracture of the through silicon via chip, thereby enhancing structural strength of the through silicon via chip.

Optionally, a lower surface of the backfill structure layer 230 is flush with a lower surface of the through silicon via chip. In this case, in the subsequent surface mounting and welding, a contact area of a bottom of the through silicon via chip is larger, which is beneficial to apportioning pressure, thereby enhancing the structural strength of the through silicon via chip.

Optionally, the wall of the oblique via may be at an angle of 60 degree with respect to an upper surface of the through silicon via chip.

It should be understood that the wall of the oblique via may also be at any angle with the upper surface of the through silicon via chip, which is not limited in the present application.

Optionally, a first insulating layer 240, a rewiring metal layer 250 and a second insulating layer 260 are orderly disposed between the backfill structure layer 230 and the silicon substrate 210.

The rewiring metal layer 250 is disposed between the backfill structure layer 230 and the silicon substrate 210, and the rewiring metal layer 250 passes through the via 220 to implement conduction between an electrical element at the upper surface of the through silicon via chip and an electronical element at the lower surface of the through silicon via chip. The second insulating layer 260 should be disposed between the rewiring metal layer 250 and the silicon substrate 210, and the first insulating layer 240 should also be disposed between the rewiring metal layer 250 and the backfill structure layer 230. The first insulating layer and the second insulating layer may be the same or different, which is not limited in the present application.

It should be understood that, a material of the insulating layer may be plastic insulation, such as polyvinyl chloride, polyethylene, or crosslinked polyethylene, and the material of the insulating layer may also be rubber, such as natural rubber, butyl rubber, or ethylene propylene rubber, which is not limited in the present application.

It should further be understood that, a height of a lower surface of the backfill structure layer 230 should be consistent with an aggregation of the through silicon via chip, the first insulating layer 240, the rewiring metal layer 250 and the second insulating layer 260 if the foregoing three layers of the through silicon via chip extend to the lower surface of the through silicon via chip.

Optionally, a material of the backfill structure layer 230 and materials of the silicon substrate 210, the rewiring metal layer 250, the first insulating layer 240 and the second insulating layer 260 are matched with each other in performance of cold and heat shrinkage.

Specifically, when a material of the backfill structure layer is selected, it should be considered that the material of the backfill structure and the material of each layer between the backfill structure and the silicon substrate 210 (i.e., the rewiring metal layer 250, the first insulating layer 240 and the second insulating layer 260) are matched in the performance of cold and head shrinkage. That is to say, the material of the backfill structure should be a material matched with silicon, and the materials of the first insulating layer, the second insulating layer and the rewiring metal layer in the performance of cold and heat shrinkage, such as rubber, plastics, or the like, which is not limited in the present application.

Optionally, a surface pad 270 is disposed at a top of the via 220, and a lower surface of the surface pad 270 is connected with the rewiring metal layer 250.

Specifically, the surface pad 270 may be disposed at the top of the via 220, and the surface pad 270 of the through silicon via chip is embedded in the upper surface of the silicon substrate 210 (i.e., the upper surface of the through silicon via chip); that is to say, the surface pad 270 covers the via 220, and is connected with the rewiring metal layer 250, that is, no insulating layer is disposed between the surface pad 270 and the rewiring metal layer 250. The via 220 may be configured in a manner that the first insulating layer 240, the rewiring metal layer 250 and the second insulating layer 260 are orderly disposed outwardly from a center axis of the via, and the rewiring metal layer 250 is connected with the surface pad 270. In this case, the surface pad 270 of the through silicon via chip is conductive with the rewiring metal layer 250 to implement electrical interconnection between an electrical element at the upper surface of the through silicon via chip and an electrical element at the lower surface of the through silicon via chip.

Optionally, a plurality of the vias 220 may be disposed on the silicon substrate 210 to implement interconnection between different surface pads of the upper surface of the silicon substrate 210, or electrically interconnection between the different surface pads of the upper surface of the silicon substrate 210 and another electrical element at the lower surface of the through silicon via chip.

Specifically, in practical production, main steps of manufacturing process of the backfill structure layer 230 are as follows:

a. Manufacture of a wafer level oblique through silicon via is completed, and FIG. 3 shows morphology of a plurality of inverted wafer level oblique through silicon via chips before a wafer is cut.

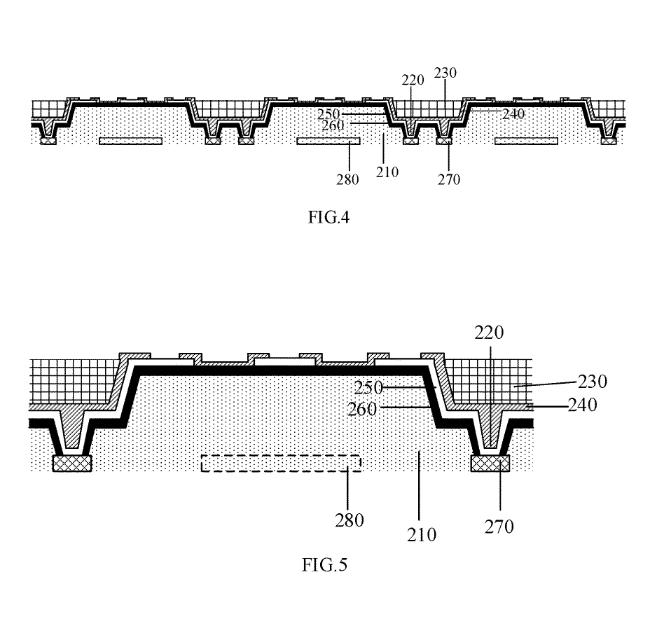

b. As shown in FIG. 4, colloid covers a back of the wafer (i.e., a hollow part of the large hole) completely by operations such as spraying or whirl coating, and colloid filled at the step is retained and the rest of collide is removed by processes such as photolithography and development. Or, a mold having a specific shape may be placed at the hollow part of the large hole, and plastics is injected into the step by injection molding.

c. The wafer is cut after completion of filling, and then an oblique through silicon via chip with a reinforced structure is obtained, as shown in FIG. 5.

It should be noted that, the foregoing application is only exemplified. In a practical case, such through silicon via chip may be generated in other manners, which is not limited in the embodiment of the present application.

An embodiment of the present application further provides a fingerprint identification sensor, where the fingerprint identification sensor includes the foregoing through silicon via chip. The through silicon via chip includes a silicon substrate, the silicon substrate is provided with a via, the via is an oblique via, and a backfill structure layer is disposed in the via, where a lower surface of the backfill structure layer is flush with a lower surface of the through silicon via chip. As shown in FIG. 2, the fingerprint identification sensor may include a pixel area 280.

An embodiment of the present application further provides a terminal device, where the terminal device includes the foregoing through silicon via chip. The through silicon via chip includes a silicon substrate, the silicon substrate is provided with a via, the via is an oblique via, and a backfill structure layer is disposed in the via, where a lower surface of the backfill structure layer is flush with a lower surface of the through silicon via chip.

According to the though silicon via chip of the embodiments of the present application, a backfill structure is added in an oblique via to play a supportive role when a test or a process such as surface bonding and welding is performed on a surface pad of the through silicon via chip, which avoids a fracture of the through silicon via chip, thereby enhancing structural strength of the through silicon via chip on the basis of low cost.

Those skilled in the art may clearly understand that, for the convenience and simplicity of description, the specific working processes of the system, the through silicon via chip and the units described above may refer to corresponding processes in the foregoing method embodiments, and will not be repeated redundantly herein.

The foregoing descriptions are merely specific embodiments of the present invention, but are not intended to limit the protection scope of the present invention. Any equivalent modification or replacement readily figured out by a person skilled in the art within the technical scope disclosed in the present invention shall fall within the protection scope of the present invention. Therefore, the protection scope of the present application shall be subject to the protection scope of the claims.

What is claimed is:

1. A through silicon via chip, wherein the through silicon via chip comprises a silicon substrate, the silicon substrate is provided with a via, the via is an oblique via, and a backfill structure layer is disposed in the via.

2. The through silicon via chip of claim 1, wherein a lower surface of the backfill structure layer is flush with a lower surface of the through silicon via chip.

3. The through silicon via chip of claim 1, wherein a first insulating layer, a rewiring metal layer and a second insulating layer are orderly disposed between the backfill structure layer and the silicon substrate.

4. The through silicon via chip of claim 3, wherein the first insulating layer, the rewiring metal layer and the second insulating layer extend to a lower surface of the through silicon via chip, and a height of a lower surface of the backfill structure layer is consistent with an aggregation of the through silicon via chip, the first insulating layer, the rewiring metal layer and the second insulating layer.

5. The through silicon via chip of claim 4, wherein a material of the backfill structure layer and materials of the silicon substrate, the rewiring metal layer, the first insulating layer and the second insulating layer are matched with each other in performance of cold and heat shrinkage.

6. The through silicon via chip of claim 3, wherein a surface pad is disposed at a top of the via, and a lower surface of the surface pad is connected with the rewiring metal layer.

7. The through silicon via chip of claim 6, wherein the surface pad is embedded in an upper surface of the silicon surface and covers the via, and no insulating layer is disposed between the surface pad and the rewiring metal layer.

8. The through silicon via chip of claim 7, wherein the first insulating layer, the rewiring metal layer and the second insulating layer are orderly disposed outwardly from a center axis of the via, and the surface pad and the rewiring metal layer are conductive with each other to implement electrical interconnection between an electrical element of an upper surface of the through silicon via chip and an electrical element of a lower surface of the through silicon via chip.

9. The through silicon via chip of claim 1, wherein a wall of the via is at an angle of 60 degree with respect to an upper surface of the through silicon via chip.

10. The through silicon via chip of claim 1, wherein the silicon substrate is provided with a plurality of the vias.

11. The through silicon via chip of claim 10, wherein the plurality of the vias are configured to implement interconnection between different surface pads of an upper surface of the silicon substrate.

12. The through silicon via chip of claim 10, wherein the plurality of the vias are configured to implement electrical interconnection between different surface pads of an upper surface of the silicon substrate and other element of a lower surface of the through silicon via chip.

13. The through silicon via chip of claim 1, wherein a material of the backfill structure layer is plastic cement or plastics.

14. The through silicon via chip of claim 13, wherein the backfill structure layer is formed in the via before a wafer is cut to obtain the through silicon via chip.

15. A terminal device, wherein the terminal device comprises the through silicon via chip, the through silicon via chip comprises a silicon substrate, the silicon substrate is provided with a via, the via is an oblique via, and a backfill structure layer is disposed in the via.

16. A manufacturing method of a through silicon via chip, used for manufacturing the through silicon via chip of claim 1, wherein the method comprises:
manufacturing a wafer level through silicon via chip on a wafer to obtain a wafer having a plurality of wafer level through silicon via chips, wherein a via of each wafer level through silicon via chip has a step structure;
filling colloid into the step structure of the wafer level through silicon chip to form a backfill structure layer;
cutting the wafer to obtain a through silicon via chip with a reinforced structure after completion of the colloid filling.

17. The manufacturing method of the through silicon via chip of claim 16, wherein the filling the colloid into the step structure of the wafer level through silicon chip comprises: covering a back of the wafer with colloid completely by spraying or whirl coating, and removing colloid on the wafer level through silicon via chip excluding the step structure by photolithography and development processes to retain colloid filled in the step structure.

18. The manufacturing method of the through silicon via chip of claim 16, wherein the filling the colloid into the step structure of the wafer level through silicon chip comprises:
placing a mold having a specific shape at a back of the wafer, and injecting plastics into the step structure with the mold by injection molding.
